(19) United States
(12) Patent Application Publication
(10) Pub. No.: US 2013/0170107 A1
(43) Pub. Date: Jul. 4, 2013

(54) Enclosure for Preventing Tampering of Mobile Communication Equipment in Transportation Industry

(71) Applicant: Doug Dean, Stillwater, MN (US)

(72) Inventor: Doug Dean, Stillwater, MN (US)

(21) Appl. No.: 13/343,201

(22) Filed: Jan. 4, 2012

(51) Int. Cl. H05K 7/00

(52) U.S. Cl. 361/679.01

(57) ABSTRACT

An enclosure configured to enclose, and prevent the tampering of, mobile communication equipment for transportation industry vehicles, and which enclosure is accessible by authorized personnel. In one preferred embodiment, the enclosure is a case configured to receive mobile communication equipment when selectively opened, and which when closed prevents the tampering with the mobile communication equipment. Openings are provided in the case such that cables and harnesses can extend from the equipment to external connectors, yet which cables cannot be accessed or tampered with while the case is closed during operation of the vehicle. The openings have restricted spacing allowing the cabling to extend there through, yet which have smaller dimensions than the equipment connectors such that the connectors cannot be disengaged or accessed by unintended personnel.

### FIELD OF THE INVENTION

The present invention is generally related to transportation industry vehicles such as delivery and long haul trucks, and more particularly to vehicles including mobile communications equipment facilitating tracking and status of the vehicle, such as onboard computers.

### BACKGROUND OF THE INVENTION

In the transportation industry, there are a variety of vehicles used for the hauling and delivery of goods. These vehicles include short range vans and trucks, as well as long-haul trucks suitable for regional and national hauling. With the advancement of mobile communications equipment, including GPS location devices and onboard computers, transportation companies are deploying the mobile communications equipment on vehicles to obtain real-time information on their fleet of vehicles. Such information may include basic location information, as well as more advanced information including vehicle specific routes, delivery schedule, current payload, and vehicle diagnostics such as engine information and tire pressure.

The transportation industry is self-regulated, but is also government regulated. The mobile communications equipment provides valuable information to both the carriers as well as the government. The government is increasingly taking a larger role in regulating the transportation industry, and many proposed regulations are in pending legislation. Vehicle information can help the government manage and track pending rulemaking. Vehicle information can help the government manage and track compliance with vehicle safety guidelines, as well other industry metrics. As with most any information, there are those who would rather prevent the distribution of information temporarily or permanently. Some drivers have been actively tampering with the mobile communications equipment, such as to hide the location of the vehicle, or prevent the delivery of the vehicle specific information. Such tampering is against company procedures, and is increasingly the subject of government regulations, both current and under review, and may be illegal.

There is desired a device and system configured to prevent the tampering of mobile communications equipment while the vehicle is in route, yet which is configured to permit access to the mobile communications equipment by authorized personnel.

### SUMMARY OF INVENTION

The present invention achieves technical advantages as a system and enclosure configured to enclose, and prevent the tampering of, mobile communications equipment for transportation industry vehicles, and permitting the equipment to be accessible by authorized personnel. In one preferred embodiment, the enclosure is a case configured to receive mobile communications equipment and permit access thereto when selectively opened, and which enclosure when closed and sealed prevents tampering with the mobile communications equipment. Openings are provided in the closed case such that cables and harnesses can extend between the equipment to external connectors, yet which cables and associated connectors cannot be accessed or tampered with while the case is closed during operation of the vehicle. The openings have restricted spacing allowing the cabling to extend there through, yet which openings have smaller dimensions than the equipment connectors such that the connectors cannot be disengaged or accessed by unintended personnel. Advantageously, the case has a base member including recesses and a retractable lid, where the recesses and lid define the openings, such that when the lid is retracted the cables can be accessed, connected/disconnected, and routed as desired.

### BRIEF DESCRIPTION OF THE DRAWINGS

FIG. 1 is a perspective view of a conventional transportation industry vehicle including mobile communications equipment installed in a tamper proof enclosure according to the present invention;

FIG. 2 is a perspective view of tamper proof enclosure in the retracted position, configured to permit access to the equipment and routed cabling/cabling connectors connected thereto;

FIG. 3 is an end view of the closed enclosure defining openings configured to route the cabling but prevent access and tampering with the cable connectors;

FIG. 4 is a top view of the tamper proof enclosure with the lid in the retracted position showing the accessibility of the cable connectors, cables, and the mobile communications equipment, wherein the cable connectors have dimensions greater than the respective openings and are seated within the enclosure;

FIG. 5 is a top view of the tamper proof enclosure of FIG. 4 with the lid in the closed position, preventing access to tampering with the internal connectors; and

FIG. 6 is a top view of the enclosure with the mobile communications material removed and depicting a securing mechanism for securing the equipment within the enclosure.

### DETAILED DESCRIPTION OF THE PRESENT INVENTION

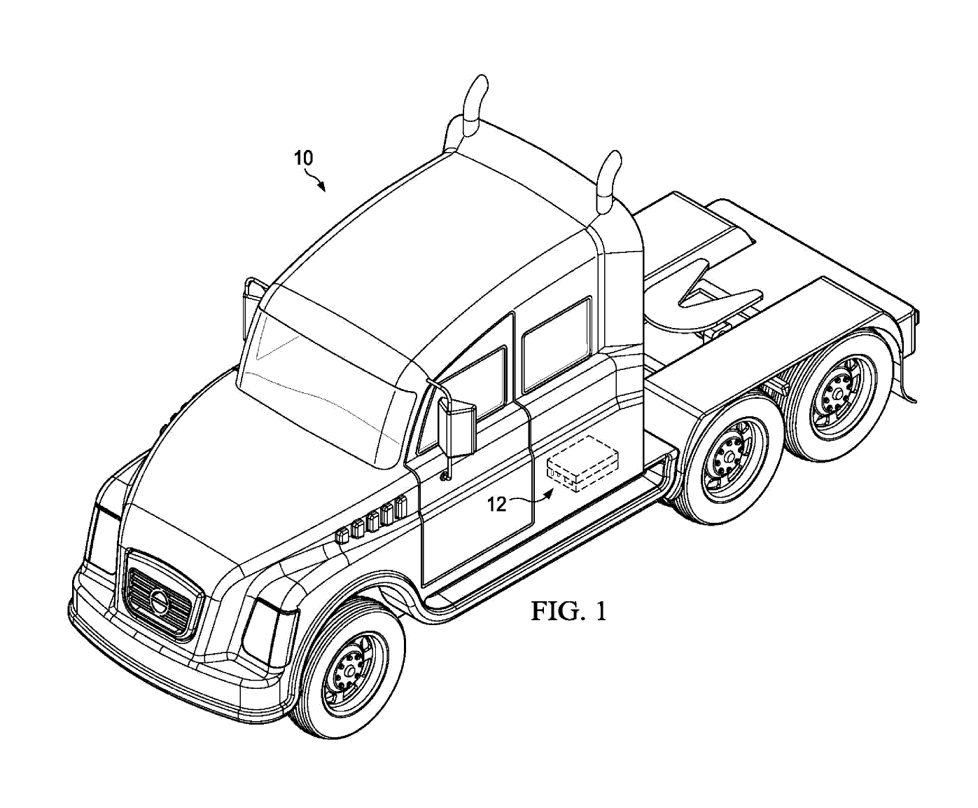

Referring now to FIG. 1 there is generally shown at 10 a perspective view of a conventional transportation industry delivery vehicle configured with mobile communications equipment disposed in a tamper proof enclosure 12 according to one preferred embodiment. The mobile communication equipment may include GPS location devices and onboard computers, configured to enable transportation companies to obtain real-time information on their fleet of vehicles. Such information may include basic location information, as well as more advanced information including vehicle specific routes, delivery schedule, current payload, and vehicle diagnostics such as engine information and tire pressure.

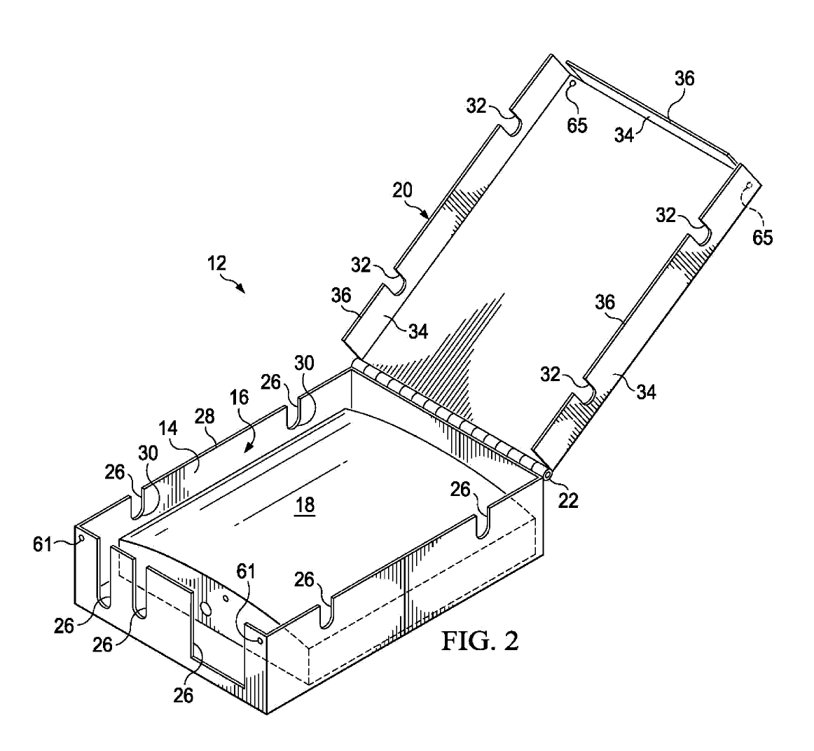

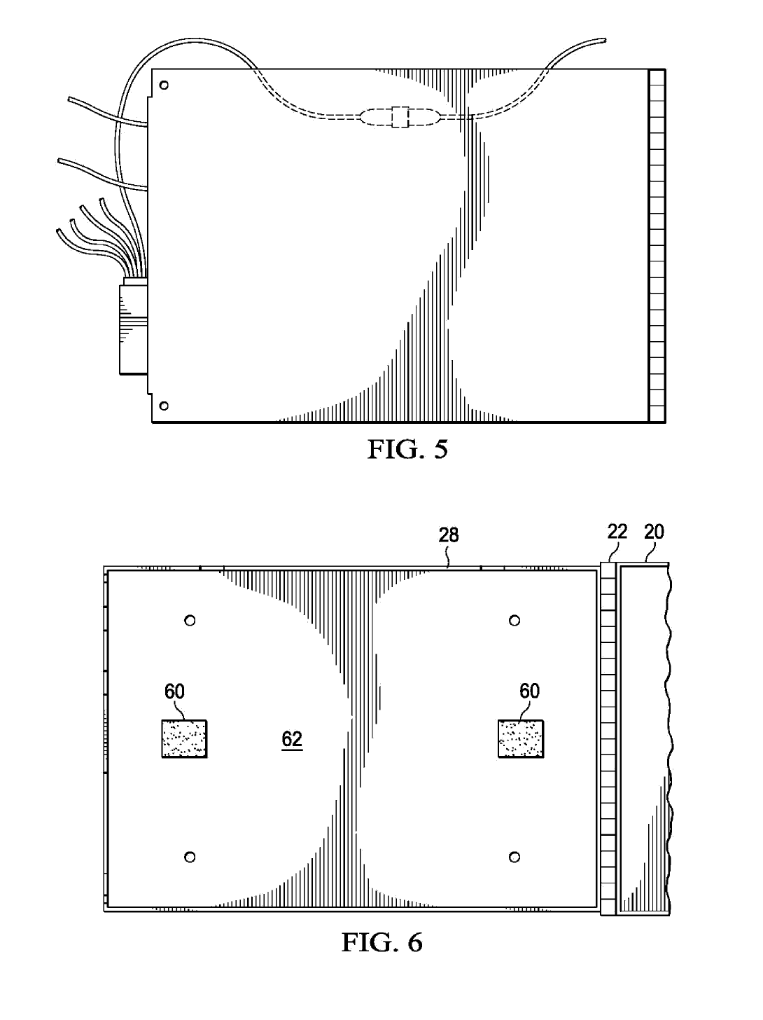

Referring now to FIG. 2, there is shown a perspective view of the tamper proof enclosure 12 having a base member including walls 14 defining a cavity 16 configured to secure mobile communication equipment 18 therein, such as an on-board computer, and a selectively retractable lid 20 joined to the base member by a hinge or pivot 22. The lid 20 is configured retract to an open position, as shown, to permit the selective accessibility to the equipment 18 as well as various connectors (not shown) coupled thereto. Defined in the various walls 14 are recesses/cut-outs 26 extending downwardly from a top edge 28 of the respective wall 14 to a lower recess edge 30. Likewise, the lid 20 has respective recesses/cut-outs 32 defined in walls 34. The walls 34 having edges 36 configured to interface and abut enclosure edges 28 when the lid 20 is in the closed position to define openings permitting cabling to extend there through, as shown in FIG. 4 and FIG. 5. The lid recesses 32 are diametrically opposed from the base member recesses 26, such that they cooperate to form a respective opening. The base member and lid may be formed of bent sheet metal, or preformed material such as plastic, metal or other desired materials suitable for intended use.

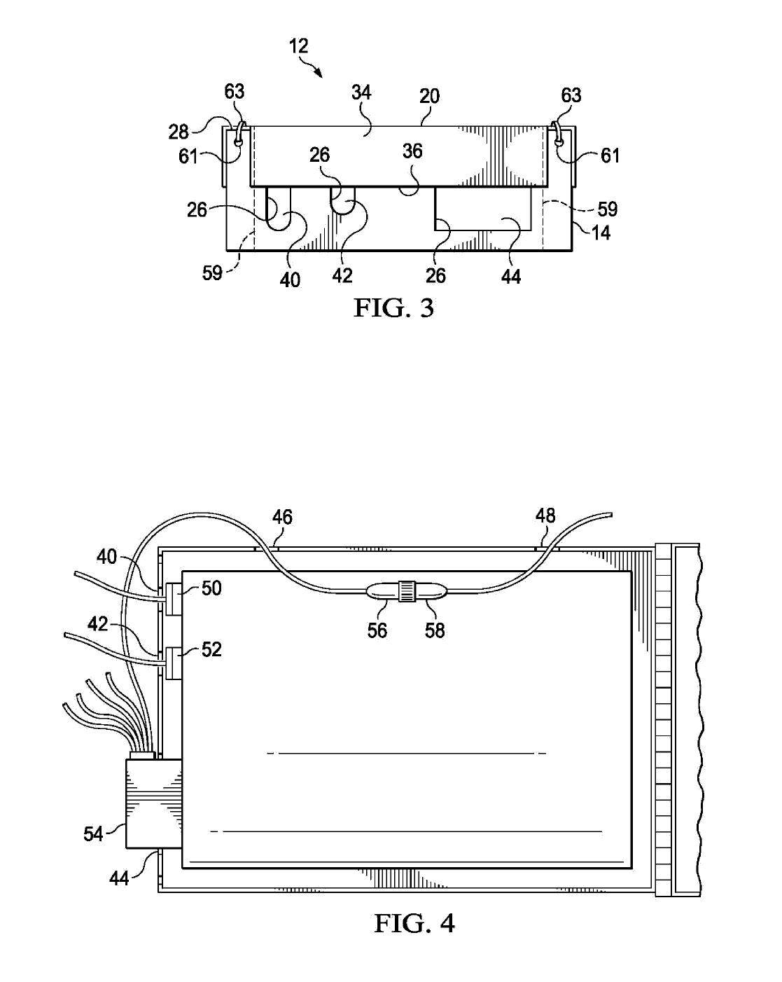

As shown in FIGS. 3 and 4, the lid 20 is in the closed position such that the lid edges 36 abut and overlap the edges 28 of the walls 14 to define openings 40, 42, 44, 46 and 48. As shown in FIG. 4, the lid 20 is in the retracted position. Advantageously, the openings 40, 42, 44, 46 and 48 have dimensions less than the width of cable connectors 50, 52, 54, 56 and 58, respectively, such that when the lid 20 is in the closed position, the cable connectors can neither be accessed, removed, tampered with, or disconnected from the device 16 connectors, such as during operation of the associated vehicle. The openings are sufficiently wide to permit the respective cabling to extend through to the respective cable connector, and also are configured to prevent chaffing of the cabling. The edges of the recesses may be smoothed, or provided with a lining to prevent chaffing of the cable during vibration in a moving vehicle. The inter face of the lid 20 and respective wall 14 is preferably provided with a mechanism to advantageously provide a visual indication when the lid 20 is subsequently opened, or when the mechanism is tampered with. The mechanism may be a seal, such as a tape, shown at 59 that is ruptured or torn when the lid is opened such that a visual indication of opening can be ascertained. This seal may include indicia such as a serial number, or a logo, for instance, that tears when tampered with or the lid 20 is opened. Alternatively, a member 63 can be extended through each opening 61 of lid 20 and through each respective opening 65 of wall 14, such as a strap or strip, which member is broken when the lid 20 is opened and which cannot be removed without damaging the member 63. The lid 20 can also be locked with a lock to the base member walls 14 to prevent unauthorized access, such as a lock extending through openings 61 and 65.

As shown in FIG. 5, the openings provide for routing of cabling essential to proper operation of the mobile communication equipment 16. By way of example, opening 40 provides routing of cabling to a GPS antenna, opening 42 provides routing of cabling to a cell antenna, opening 44 provides routing of cabling providing a computer data and power cable, and openings 46 and 48 provide routing of cabling to connectors 56 and 58 providing an ECM connection.

FIG. 6 shows a top view of the enclosure 12 with the lid 20 retracted and the mobile communication equipment 18 removed, depicting a securing mechanism 60 disposed on the base wall 62 defining the cavity 16. The securing mechanism 60 is configured to secure the mobile communication equipment 18 to the base wall 62 to prevent damage thereto during use, and may also provide vibration dampening. Suitable securing mechanisms 60 may include adhesive, foam, or Velcro material manufactured by 3M Corporation.

Though the invention has been described with respect to a specific preferred embodiment, many variations and modifications will become apparent to those skilled in the art upon reading the present application. The intention is therefore that the appended claims be interpreted as broadly as possible in view of the prior art to include all such variations and modifications.

What is claimed is:

1. A tamper proof system including an enclosure for mobile communications equipment configured to provide data indicative of a transportation delivery vehicle, comprising:
a base member comprising at least one wall defining a cavity configured to receive the mobile communications equipment, the at least one wall having a top edge and at least one recess extending downwardly from the top edge, the recess having a first dimension;
mobile communications equipment disposed in the cavity and having at least one device connector disposed proximate the recess;
a retractable member configured to retract from the base member to an open position to permit access to the mobile communications equipment, and also configured to have a closed position proximate the at least one recess to form at least one enclosure opening; and
a cable extending through the at least one enclosure opening and having a cable connector configured to connect with the device connector, the cable connector having a dimension greater than the at least one enclosure opening, the at least one enclosure opening configured to prevent tampering with the cable connector when the retractable member is in the closed position.

2. The tamper proof system as specified in claim 1 further comprising a member coupled to the base member and the retractable member that is configured to be ruptured or broken when the lid is retracted to the open position.

3. The tamper proof system as specified in claim 1 wherein the cable is configured to provide signals configured to control the operation of the mobile communications equipment.

4. The tamper proof system as specified in claim 3 wherein the retractable member has an interface proximate the base member at least one recess in the closed position to define the at least one enclosure opening.

5. The tamper proof system as specified in claim 3 wherein the retractable member has at least one recess configured to be positioned proximate the base member at least one recess to define the at least one enclosure opening.

6. The tamper proof system as specified in claim 5 wherein the retractable member at least one recess is diametrically opposed from the base member at least one recess.

7. The tamper proof system as specified in claim 1 wherein the retractable member is joined to the base member at a hinge.

8. The tamper proof system as specified in claim 1 wherein the at least one enclosure opening is configured to prevent chaffing of the cable extending there through.

9. The tamper proof system as specified in claim 1 wherein the transportation vehicle is a commercial motor vehicle.

10. The tamper proof system as specified in claim 1 wherein the base member and retractable member define a plurality of the enclosure openings, at least one cable extending through each of the enclosure openings and connected to the mobile communications equipment.

11. A system, comprising:
a transportation delivery vehicle;
a tamper proof system coupled to the transportation delivery vehicle including an enclosure for mobile communications equipment configured to provide data indicative of a transportation delivery vehicle, the tamper proof system comprising:
a base member comprising at least one wall defining a cavity configured to receive the mobile communications equipment, the at least one wall having a top edge and at least one recess extending downwardly from the top edge, the recess having a first dimension;
mobile communications equipment disposed in the cavity and having at least one device connector disposed proximate the recess;
a retractable member configured to retract from the base member to an open position to permit access to the mobile communications equipment, and also configured to have a closed position proximate the at least one recess to form at least one enclosure opening; and
a cable extending through the at least one enclosure opening and having a cable connector configured to connect with the device connector, the cable connector having a dimension greater than the at least one enclosure opening, the at least one enclosure opening configured to prevent tampering with the cable connector when the retractable member is in the closed position.

12. The tamper proof system as specified in claim 11 further comprising a member coupled to the base member and the retractable member that is configured to be ruptured or broken when the lid is retracted to the open position.

13. The system as specified in claim 11 wherein the cable is configured to provide signals configured to control the operation of the mobile communications equipment.

14. The system as specified in claim 13 wherein the retractable member has an interface configured proximate the base member at least one recess in the closed position to define the at least one enclosure opening.

15. The system as specified in claim 13 wherein the retractable member has at least one recess configured to be positioned proximate the base member at least one recess to define the at least one enclosure opening.

16. The system as specified in claim 15 wherein the retractable member at least one recess is diametrically opposed from the base member at least one recess.

17. The system as specified in claim 11 wherein the retractable member is joined to the base member at a hinge.

18. The system as specified in claim 11 wherein the at least one enclosure opening is configured to prevent chaffing of the cable extending there through.

19. The system as specified in claim 11 wherein the transportation vehicle is a commercial motor vehicle.

20. The system as specified in claim 11 wherein the base member and retractable member define a plurality of the enclosure openings, at least one cable extending through each of the enclosure openings and connected to the mobile communications equipment.
